(19) United States
(12) Patent Application Publication
(10) Pub. No.: US 2022/0122864 A1
(43) Pub. Date: Apr. 21, 2022

(54) SMART SKIP TESTING METHOD FOR SEMICONDUCTOR MANUFACTURING

(71) Applicant: Inference Tech, s.r.o., Praha (CZ)

(72) Inventors: Petr LENHARD, Hostivice (CZ); Radomir LENHARD, Roznov pod Radhostem (CZ)

(21) Appl. No.: 17/074,723

(22) Filed: Oct. 20, 2020

(51) Int. Cl. H01L 21/67; G06N 5/04; G06N 20/00

(52) U.S. Cl. CPC H01L 21/67276; G06N 20/00; G06N 5/04

(57) ABSTRACT

Provided is a method for predicting and classifying yield to determine downstream testing steps. The method comprises obtaining and preprocessing historical input data from a semiconductor fabrication process, setting a yield threshold for a yield classification, and training a model using the historical input data as a training dataset. The model is configured to determine from a set of input data whether any of the wafers or lots have higher yield than the yield threshold and can skip next testing. The yield threshold is optimized during the model training to identify an optimal yield threshold at which total cost of wafer sorting, die assembly, and final test is minimal. The trained model is deployed and used for the yield prediction and classification using real time input data from semiconductor manufacturing, resulting in substantial savings in cost and test time and effectively increasing test capacity.

### CROSS-REFERENCE TOLERATED APPLICATIONS

Not applicable.

### TECHNICAL FIELD

This disclosure relates generally to semiconductor manufacturing processes, and more particularly, to method for using semiconductor manufacturing data to predict and classify yield to optimize downstream testing steps.

### BACKGROUND

Semiconductor device manufacturing involves complex processes to produce integrated circuits (IC).

FIG. 1 (prior art) illustrates one possible flow 100 of semiconductor manufacturing. It gives a high-level view of the basic steps that can be taken in making a semiconductor device, while there may actually be hundreds of more detailed steps.

Wafer fabrication occurs in step 110, where a large number of integrated circuits are formed on a single slice of semiconductor substrate, such as silicon, known as a wafer. Plurality of wafers is transferred and processed in lots. The current convention is a lot size of 25 wafers but it can be also a smaller value. Many steps are required in various sequences to build different integrated circuits. For example, deposition of an insulating layer, diffusion, ion implantation, photo-masking, etching, metal deposition and passivation. The fabrication process can take several months to complete before moving on to the post-fabrication steps.

Integrated circuits typically receive a wide variety of testing throughout the fabrication process, both to ensure that the processes used to fabricate the integrated circuits are in control, and also to ensure that the structures formed by the various processes have the proper characteristics. This type of testing is generally referred to as in-process testing herein.

A fabricated semiconductor wafer undergoes evaluative testing to ensure the integrated circuits are formed correctly and that they operate in a desired manner. In step 120 a Process Control Monitoring (PCM) also known as Wafer Acceptance Test (WAT) or Class Probe (CLP) collects parametric test data regarding the quality of the wafers at different stages of wafer fabrication. The test structures are distributed across the wafer surface, either in die sites or in the scribe lines between dice.

The PCM measurement is followed by comprehensive tests in step 130 performed on each IC die, commonly called Wafer Sort (WS), and also known as Circuit Probe (CP) or Unit Probe (UP). The dice may either pass or fail the testing procedure. Failed dice will be marked with a black dot in the middle of the die, or alternatively, the information about passing/failed dice is stored in an electronic file named Wafer Map (WM), also known as Wafer Bin Map (WBM) or Electronic Wafer Map (EWM). The wafer map also specifies excluded dice as edge dice around the wafer circumference, test structures and alignment dice. So after cutting the wafer failed and excluded dice can be separated from the good dice. The yield at WS is calculated as the ratio of good dice to all dice on an individual wafer that entered into the WS.

Die Assembly (ASSY) takes place in step 140. The wafer is diced up into separate individual die, and each die that passed at the WS is bonded to and electrically connected to a frame. Each die attached to the frame is then encapsulated to protect the circuit.

In step 150, the integrated circuit is tested once again by automated test equipment. This is called final testing (FT). Only the integrated circuits that pass the tests will be shipped to customers.

There is a need for minimizing testing time requirements during product fabrication yet maintaining acceptable quality control levels, resulting in lower production cost. The largest possible reduction in testing time would be to test each parameter only once either by skipping the Wafer Sort in step 130 or step 150 of Final Testing completely, or by splitting up these tests over the WS and FT, reported as concurrent testing. Skipping the FT may be done, but it is risky due to several production steps after the WS like inking, grinding and sawing, which may damage the integrated circuit. Also a relevant factor is that due to assembly, mechanical stress within the silicon dice itself, caused for example by the pressure of the plastic, results in additional fails. Due to this stress, parts may become an open or a short.

If the WS step 130 is skipped the WS costs are eliminated, while the FT step 150 costs are increased due to a lower yield at the FT and the additional costs of the ASSY step 140 of the failing products. Also without the WS that can provide an accurate assessment of actual performance by the IC die, wafer fab induced yield problems may not be discovered for weeks or months after the wafer has completed its processing in the wafer fab. This long delay between wafer fab processing and testing can jeopardize deliveries to the customer and prevent prompt feedback to the wafer fab needed for timely process correction, which means that all wafers produced during the corresponding time interval can be worthless too.

To reduce their testing time at the WS, manufacturers are testing multiple devices simultaneously, thus increasing the numbers of pins required on a probe card.

Several types of adaptive WS methods based on test results have been disclosed—for example, (1) test time reduction or (2) sample probe.
(1) According to the test time reduction method various forms of wafer fabrication data are used to determine the most effective set of tests to run, and the best sequence in which to run them, on a given product. In another method, an adaptive test sequence for testing integrated circuits is used based on a frequency of fails of the test item in the testing of a plurality of devices.
(2) The sample probe method comprises the steps of generating test-data at a limited number of dice on the wafer, deciding based on the generated test-data whether other dice on the wafer are to be tested, and based on the result of the deciding step, testing or not testing the other dice on the wafer.

The above adaptive WS methods, although leading to the wafer test time reduction, still require that all wafers be loaded on the prober chuck, wafer pads are aligned to the probe tips, the wafer is tested, and unloaded back into the carrier.

Machine Learning models are used on extensive sets of process input data to correlate the input data to specific features of interest. The correlations can then be used to make process adjustments. The Machine Learning techniques may be applied to process features or yield prediction. It is possible to apply different models to different input data types to ensure that the model accurately predicts the result value.

For example, if the prediction result is yield, then if the predicted yield is below a predetermined minimum yield limit, the wafer may be sent to a responsible department for further testing or wafer processing may be terminated.

There is a need for a method that can adaptively identify products that can skip the wafer level test altogether, resulting in substantial cost savings, increased testing capacity, and reduced production cycle time.

### SUMMARY

In accordance with present invention a method for predicting and classifying unit yield, where unit can be a wafer or group of wafers such as a lot to determine downstream testing steps, comprises obtaining and preprocessing historical input data, setting a yield threshold for yield classification, and training a model using the historical input data as a training dataset. The model is configured to determine from a set of input data whether any of the units have higher yield than the unit yield threshold and can be skipped from the next testing. The yield threshold is optimized during the model training to identify an optimal yield threshold at which a total cost of wafer sorting, die assembly, and final test is minimal. The trained model is deployed and used for the yield prediction and classification using a stream of real time input data from semiconductor manufacturing.

### BRIEF DESCRIPTION OF THE DRAWINGS

FIG. 1 is a flow diagram with the illustrated process of making a semiconductor device (prior art).

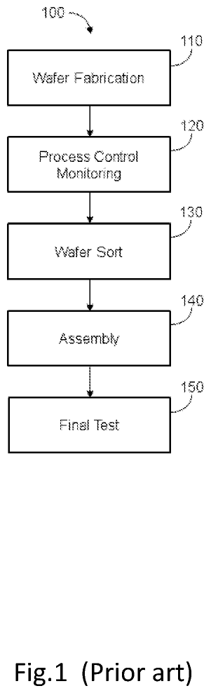

FIG. 2 is a flow diagram illustrating one embodiment of the method for wafer yield classification model training.

FIG. 3 is a flow diagram illustrating a prediction with the wafer yield classification method.

FIG. 4 is a graph plotting the total cost of Wafer Sort, Assembly, and Final Test as a function of yield threshold Yr.

FIG. 5 is a flow diagram illustrating an additional embodiment of the method for lot yield classification model training.

FIG. 6 is a flow diagram illustrating a prediction with the lot yield classification method.

### DETAILED DESCRIPTION

### 1. Overview

A method is described for using semiconductor in-process, PCM and WS data to adaptively modify production testing steps. In general, the embodiments described herein may be referred to as Smart Skip Testing method. The wafer level testing can include but is not limited to an individual die functional and reliability testing, or specific tests that employ high-temperature, high voltage testing or the like.

It is an object of the present invention to provide test cost reduction related to wafer level testing of IC's, diodes and transistors, in general of any device manufactured on a semiconductor wafer.

It is a further object of the present invention to significantly leverage the available test capacity for the wafer level testing of semiconductor devices, which in turn will increase the effective probe capacity.

Another object is to reduce the production cycle time, when a wafer or a lot that skip the WS can be sent directly to the next process step, such as assembly, after the wafer maps have been generated.

The above objects as well as further objects that will become apparent from an ensuing description are accomplished by a method according to the present invention.

### 2. Machine Learning

Machine Learning (ML) is a subset of Artificial intelligence (AI) and is located at the intersection of Statistics and Computer Science. ML/AI can be used to analyze large volumes of data and to generate predictions that help make pass/fail recommendations. Such recommendations can increase in accuracy with the volume of data analyzed. Moreover, by retraining the ML models, the recommendations can adapt to the latest distribution of the data. ML/AI is particularly useful for analysis of modern chip manufacturing and test data due to its ability to uncover nonlinear interactions in highly multidimensional data, as well as identify features that are important in predicting eventual die outcomes. The ML/AI approach is sensitive to the quality of the data and can be computationally intensive. Careful attention must therefore be paid to the statistical robustness of the results and to effective parallelization of the computational process.

The ML/AI methods open up the possibility of incorporating data analysis to make adjustments to the process flow in order to reduce cost and optimize processes including inventory management and control. Thus, if yield excursions can be predicted for a given wafer population, then those wafers could be routed for complete testing. Conversely, if yield is predicted to be good, then that wafer population could undergo a much lighter testing down the line.

Predictive analytics and ML/AI algorithms can thus be used to address many of the challenges facing the semiconductor industry. By drilling deeper into the details of semiconductor manufacturing and knowing how to apply predictive analytics to detect and resolve process issues faster, and to tighten and target the specifications of individual manufacturing steps, increased process efficiencies can result. Some of the known ML algorithms include but are not limited to: a tree-based algorithm, a neural net based algorithm, neighborhood-based approach, and others.

### 3. Machine Learning Method for Smart Skip Testing

Any machine learning model is created in a process called training (including validation and testing), and then applied to accomplish prediction. The model is trained for a unit yield classification, where the unit may correspond to a wafer or group of wafers such as a lot.

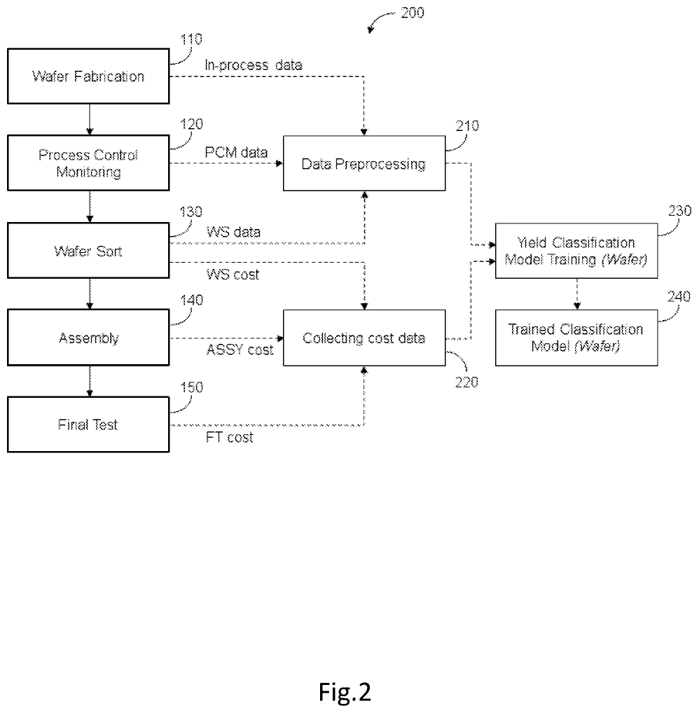

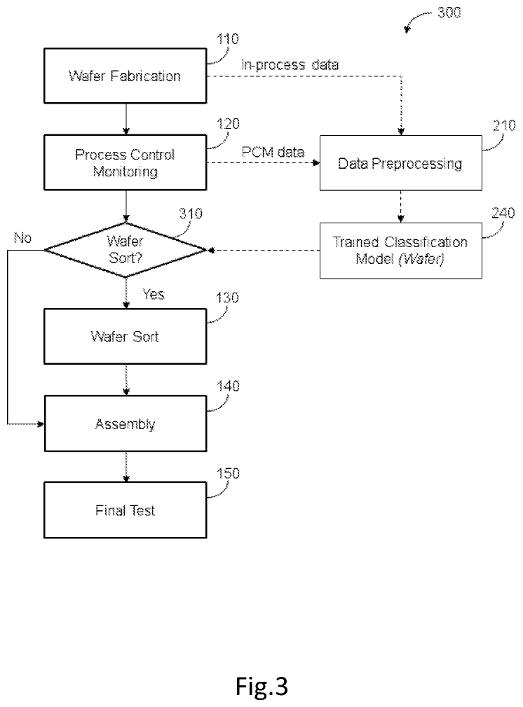

In one embodiment the training process 200 of the wafer yield classification model is illustrated in FIG. 2, and the prediction process 300 is illustrated in FIG. 3.

The training process involves providing data from various stages of the semiconductor process to learn from. The training data may comprise some or all of the following types of historical input data: in-process data, PCM data, WS, ASSY and FT cost data, and labeling data that can be wafer yield acquired from the WS data.

The data is preprocessed in step 210 of FIG. 2, where the raw data is prepared to be suitable for a machine learning model. The preprocessing may include techniques like cleaning, integration, normalization and balancing. Data is cleaned through processes such as removing outliers, imputing missing values or resolving the inconsistencies and errors in the data. An outlier is a data point that lies outside the overall pattern in a distribution. Data with different representations are integrated together and conflicts within data are resolved. For example, in-process measurement and defect data, PCM data and WS data can be integrated into a single environment. The normalization is used to change the values of numeric columns in the dataset to a common scale, without distorting differences in the ranges of values. For example, in the case of a capacitor and resistor values, the difference between the values may exceed several orders of magnitude. The dataset balancing with respect to the response variable (e.g. the wafer yield) may be needed to balance weights of the underrepresented cases.

In step 230, an appropriate training algorithm is run on the preprocessed data to train the wafer yield classification model. Not all data listed above are required. The output of the training step 230 is a trained model 240.

FIG. 3 illustrates one possible flow in the classification process 300 of semiconductor manufacturing with the Smart Skip Testing method. Data preprocessing unit in step 210 obtains real time data from the production run in step 110, and step 120, and then feeds the data into the trained wafer yield classification model 240 where the classification is made. The trained model 240 can output a recommendation for wafer to be sent to WS or to skip the WS. The output can be provided in various formats, such as CSV files, or sent directly as a decision into the Manufacturing Execution System 310, which controls the manufacturing process flow in real time.

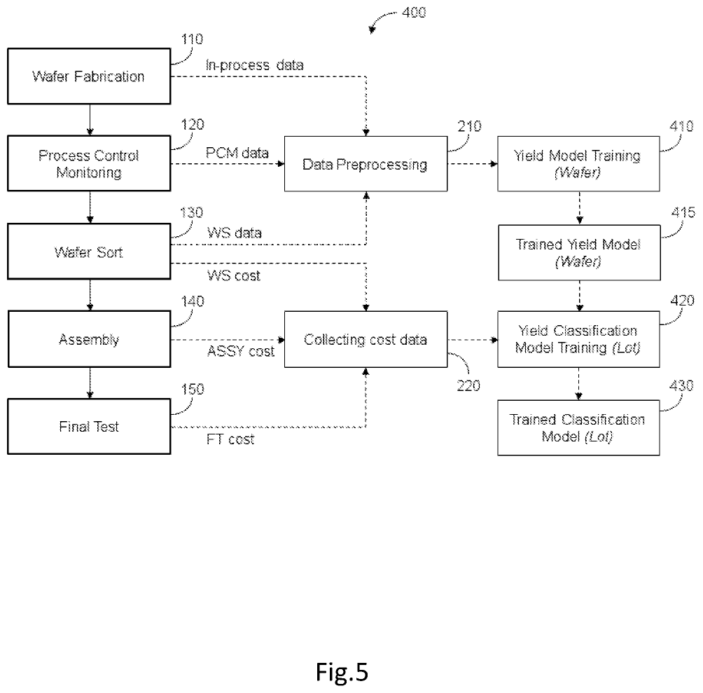

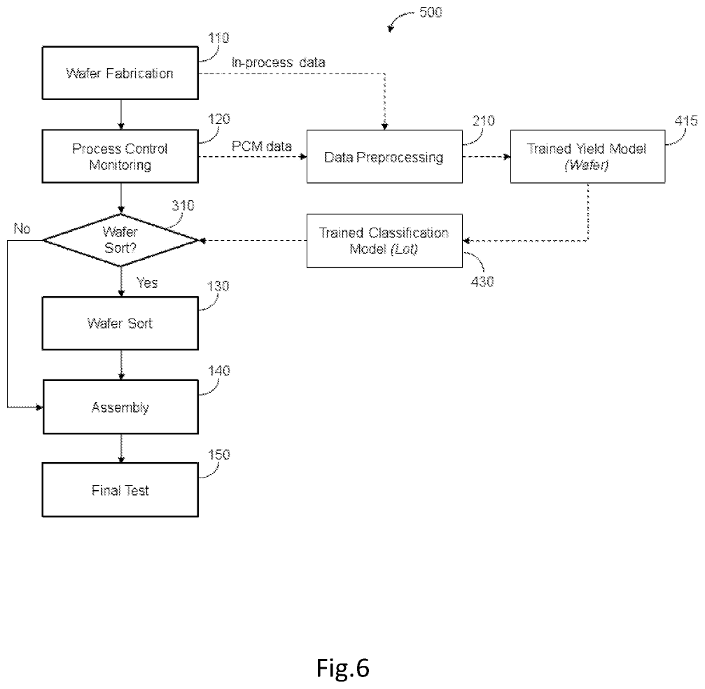

In another embodiment the process can be implemented to provide a lot classification. In this embodiment the training process 400 of the lot yield classification model is illustrated in FIG. 5, and the prediction process 500 is illustrated in FIG. 6. The predicted yield for each wafer in the lot is provided by the trained wafer yield model 415 of FIG. 5, which is then used for the lot classification model training in step 420. The trained model 430 of FIG. 6 can output a recommendation for lot to be sent to WS or to skip the WS.

### 4. Method Modules

In one embodiment, the Machine Learning method disclosed herein includes following modules: (A) input and labeling data; (B) data preprocessing; (C) yield threshold for classification, (D) model training; (E) prediction and classification.

A. Input and Labeling Data

The training step can require some or all of the following types of historical input data: in-process data comprising measurement and defect data; PCM data; WS, ASSY and FT cost data; and labeling data that is wafer or lot yield acquired from the WS data.

The in-process data is obtained in step 110 of FIG. 2 from different stages of the wafer fabrication. The in-process data can be divided into measurement data and defect data. The measurement data may include but is not limited to data indicating a line width, a dielectric film thickness, an etch depth, a layer resistivity, and misalignment of a circuit. The measurement data may use text data as well as image data. The defect data refers to data indicating the number of defects, a defect size, a defect position, a defect shape, or the like. Defect data may also be image data or may use text data.

In step 120 the PCM data is taken directly from the various test structures placed on at least a few predefined test sites per wafer (e.g. 5, 9, 13, etc.) or on all test sites. A large number of electrical parameters are measured from the test structures. These measurements may include but are not limited to a MOS transistor threshold voltage, a gate width, a current gain, a breakdown voltage, a contact and a via chain resistance, film resistor properties, interconnect integrity, and interconnect resistance.

The WS data is the result of step 130 from performing a plurality of, generally electrical, tests on individual integrated circuits formed on the wafers. These tests verify the functionality of the finished circuits. The labeling or bin data (die pass/fail) is acquired from the WS data and is used as a response for yield prediction and classification during the training process.

The cost data 220 is collected as a wafer sort in step 130 cost per wafer, die assembly in step 140, and final test in step 150 costs per device or package. The cost data can be updated on regular basis or if a systematic change is made.

The prediction step can require the same data as the training step, except for the labeling data.

Data inputs can be made available through a variety of methods, including but not limited to: download from relational, or NoSQL database and direct parsing from CSV or XML files in specified file location (e.g. cost data). Data download can be operated in both interactive and automated regimes.

B. Data Preprocessing

In one embodiment, the downloaded data is converted into data appropriate to be inputted to the ML models. The data preprocessing may be performed differently according to data types and characteristics.

Specifically, the following are some examples of data validations that can be included in the disclosed method (non-exhaustive list): comparison of common statistical quantities against predefined limits; use of minimum, maximum, average, standard deviation, percentiles, correlations; uniqueness checks for categorical and string data types (e.g. lot ids, wafer ids); check for date and time-stamp validity.

In addition, data anomalies like outliers can be identified with different techniques, including but not limited to: ML algorithms such as local outlier factor, isolation forests, and DBSCAN as well as statistical method that uses the interquartile range (IQR) to calculate the boundaries for what constitutes outliers. Data point is an outlier if it is beyond range of the first quartile minus the multiple of IQR to the third quartile plus the multiple of IQR. A common value for the IQR multiple is in the range of 1.5 to 6, but it can also have a higher value.

In addition, missing data points, including removed outliers can be replaced with values such as upper value, lower value, or median value as well as with values that can be predicted with algorithm such as k nearest neighbors (k-NN) or multivariate imputation by chained equations (MICE).

In addition, if features in datasets have different ranges, normalization can be used to rescale the input and output variables to values between 0 and 1 before to training models.

In addition, dataset balancing with respect to the response might be necessary.

In addition, some or all of the following data inputs are integrated into a single environment: in-process measurement and defect data, PCM data, WS data, and cost data of WS, ASSY and FT.

C. Yield Threshold for Classification

If a set of wafers with a certain yield distribution is split into wafers with lower yield than a yield threshold (Y_{T}) that are tested at the WS and the remaining wafers skip the WS then the total costs (TC) of WS in step 130 in FIG. 2, ASSY in step 140 and FT in step 150 can be calculated using the following expression:

$$TC = \frac{{N}_{WS} \cdot {C}_{WS} + {\sum }_{i = 1}^{Nskip} PDPW \cdot ( 1 - {Y}_{i} ) \cdot {C}_{AFT}}{{N}_{WS} + {N}_{Skip}}$$

where N_{WS} is number of wafers tested at WS, C_{ws} is the cost of WS per wafer, N_{Skip} is number of wafers that skipped the WS, PDPW stands for Potential Die Per Wafer, which is the total number of dice on a wafer, Yᵢ is the yield of a particular wafer that skipped the WS, and C_{AFT} is the cost of Assembly and Final Testing per device or package.

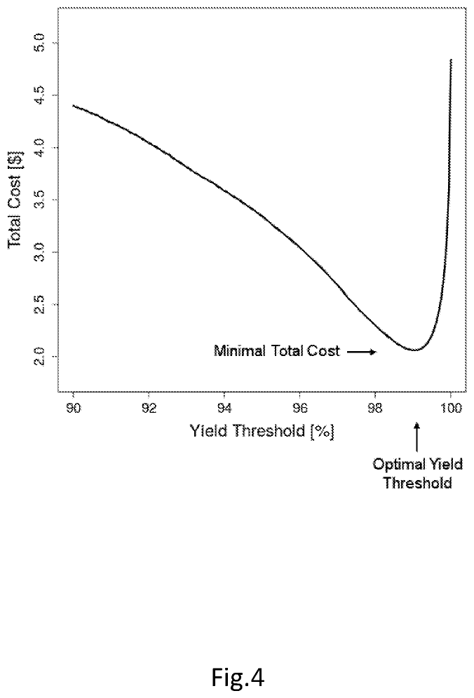

The choice of yield threshold Y_{T} affects the split of the wafer set in N_{WS} and N_{Skip}. FIG. 4 is a graph plotting the total cost of Wafer Sort in step 130 in FIG. 2 and FIG. 3, Assembly in step 140 and FT in step 150 as a function of yield threshold Y_{T}. High Y_{T} results in a situation where most of the wafers are sent to the WS in step 130, so the TC is dominated by the WS cost. Conversely, low Y_{T} causes most wafers to skip the WS and the TC is increased due to lower FT yield and additional ASSY costs for the failing products. The optimal yield threshold (Y_{TO}) in FIG. 4 is the threshold at which the total cost (TC) is minimal i.e.:

$${Y}_{TO} = {argmin}_{{Y}_{T} ∈ [ 0 , 1 ]} TC ( {Y}_{T} )$$

If the yield can be accurately predicted after step 120 of FIG. 3, then with the classification method/model 240 that is trained with respect to Y_{TO}, the lowest possible total cost can be achieved for a given production flow.

If there are any further steps in the process flow in the classification process 300 between WS in step 130 and FT in step 150, the related costs can be added to the above mentioned expression.

The yield threshold setting can be determined also in a different way depending on which process or cost characteristic is most important for the user.

D. Model Training

As described earlier, the inputs to the model training step 230 of FIG. 2 are some or all of the following types of historical data: in-process data; PCM data; WS, ASSY and FT cost data. The labeling data is the wafer or lot yield acquired from the historical WS data. The data is split into several datasets so that training, validation, and testing techniques are applied to determine the best model. Various models are tried using different ML algorithms such as Classification and Regression Tree (CART), Random Forest, Extra Tree, Gradient Boosting Machine, Alternating Model Tree, Artificial Neural Network (ANN), Recurrent Neural Network (RNN), Restricted Boltzmann Machine (RBM), Deep Learning and others. Results from multiple models can be combined in an ensemble model to improve the overall performance.

The model or ensemble model that best meets desired goals represented by the objective function is selected. As the objective function it can be used standard ML metric such as mean square error, mean absolute error, or mean square error with an additional penalty function to penalize for missing desired specification. The objective function can be customized depending on which metric is of the most importance to the user.

The yield threshold can be optimized during the yield model training to identify the optimal yield threshold Y_{TO} at which the total cost of wafer sorting, die assembly, and final test is minimal with respect to the model's characteristics.

The model is trained to provide a unit classification. In one embodiment in FIG. 2, the unit corresponds to a wafer, and in another embodiment in FIG. 5, the unit corresponds to a lot.

Method 1: Wafer Level

The wafer yield classification model is trained in step 230 of FIG. 2. The trained model 240 predicts whether the wafer yield is higher or lower than the optimal wafer yield threshold Y_{TO}. The output of the classification can be one of two values namely, either “WS” or “skip WS” (or “test” or “skip test” or “high yield” or “low yield” or “good” or “bad”). For example, if the classification prediction for a wafer is “WS”, then it is predicted that the wafer have lower yield than Y_{TO} and should continue processing at the WS. If the classification is predicted to be “skip WS,” then this wafer is predicted to have higher yield than Y_{TO}, and it is recommended to skip WS and continue processing with the next step.

Method 2: Lot Level

An alternative approach to the wafer yield classification model would be a lot yield classification model. In this method, the first step 410 of FIG. 5 is to train the wafer yield model to predict the yield for each wafer in the lot. Response data of the trained wafer yield model 415 is used for the lot classification model training in step 420. The trained model 430 predicts whether the lot yield is higher or lower than the optimal lot yield threshold Y_{TO}. The output of the classification may have the same categories as the wafer classification, i.e. either “WS” or “skip WS” (or “test” or “skip test” or “high yield” or “low yield” or “good” or “bad”). For example, if the classification prediction for a lot is “WS”, then it is predicted that this lot have lower yield than Y_{TO} and should continue processing at WS. If the classification is predicted to be “skip WS,” then this lot is predicted to have higher yield than Y_{TO}, and it is recommended to skip WS and continue processing with the next step. The optimal yield threshold Y_{TO} for the wafer classification and lot classification may have a different value.

The output of the model training step can be an executable trained model 240 of FIG. 2 or 430 of FIG. 5 to be used in the prediction step. Model training can be triggered either manually by the user or on a user-defined time interval.

E. Prediction and Classification

In one embodiment in FIG. 3 the prediction and classification is provided at the wafer level, and in another embodiment in FIG. 6, the prediction and classification is provided at the lot level.

Method 1: Wafer Level

FIG. 3 illustrates the wafer yield prediction and classification. New incoming data or real-time data for prediction is automatically preprocessed in step 210 to ensure the quality of prediction and that the model assumptions are not violated. The same preprocessing approach is applied as previously during model training. The prediction step can use some or all of the following types of new data: in-process measurement data, defect data, and PCM data from production in conjunction with the deployed model object generated in the model training step to produce a wafer yield classifications. The classification in this context refers to decision in step 240 as to whether a given wafer should be sent to the WS or skip testing at the WS. The decision can be directly sent to the Manufacturing Execution System 310.

Method 2: Lot Level

FIG. 6 illustrates the lot yield prediction and classification. New incoming data or real-time data for prediction is automatically preprocessed in step 210 and sent to step 415 to predict the yield for each wafer in a lot. The classification in this embodiment refers to decision in step 430 as to whether a given lot should be sent to the WS or skip testing at the WS. The decision can be directly sent to the Manufacturing Execution System 310.

Thus, yield prediction and classification are useful in determining how to proceed with a wafer or lot processing in a cost-effective manner. The yield prediction and classification are not necessarily the only variable in making a decision how to continue processing of a product.

A wafer map is also generated for wafers skipped at the WS before being sent to assembly. In this case, there is information about the excluded dice.

The method can also include actions that increase the method robustness. For example, in case that a new input data issue like missing parameters or unusual behavior are detected during automated preprocessing, the method can be specified to mark all wafers as requiring testing or to trigger a model retraining request. Additionally, warning can be applied to inform the user when the number of wafers tested at the WS has changed beyond certain preset values.

### 5. Conclusion

The Smart Skip Testing method aims to identify incoming wafers or lots that are likely to pass tests with yield above the optimal yield threshold, and recommends that the identified wafers or lots skip the test altogether, resulting in substantial cost savings, increased effective testing capacity, and reduced production cycle time. Disclosed method is a real time method that is able to make cost-effective decisions without human intervention.

The foregoing written description is intended to enable one of ordinary skill to make and use the techniques described herein, but those of ordinary skill will understand that the description is not limiting and will also appreciate the existence of variations, combinations, and equivalents of the specific embodiments, methods, and examples described herein.

The data and the machine learning techniques mentioned in the above-described embodiments are merely examples, and may be replaced with others.

The invention claimed is:

1. A method for predicting and classifying yield to determine downstream testing steps, comprising:
obtaining and preprocessing historical input and labeling data from a semiconductor fabrication process,
setting a unit yield threshold for unit yield classification,
training of at least one unit yield model using historical input and labeling data as a training dataset, the unit yield model trained to determine from the training dataset whether any of the plurality of units have yield higher than the unit yield threshold and can skip next testing step,
deploying of at least one unit yield model to evaluate the input of a current production unit, predicting, by employing the trained unit yield model and current input data, whether the unit has higher yield than the unit yield threshold,
recommending whether the unit can skip next testing step.

2. The method of claim 1, wherein the input data is selected from a data group consisting of in-process data, and process control monitoring data from a semiconductor fabrication process and labeling data is the unit yield acquired from historical wafer sort data.

3. The method of claim 1, further comprising:
acquiring an ensemble of cost data from wafer sorting, die assembly, and final test process steps,
setting the unit yield threshold for unit yield classification, wherein the cost data is used for the unit yield threshold calculation.

4. The method of claim 3, further comprising:
optimizing the unit yield threshold during unit yield model training to identify an optimal unit yield threshold at which the total cost of wafer sorting, die assembly, and final test is minimal with respect to the model's characteristics.

5. The method of claim 4, further comprising:
predicting by employing the trained unit yield model using the current input data, whether a unit has higher yield than the optimal unit yield threshold.

6. The method of claim 1, wherein the unit corresponds to a wafer and the unit yield model is a wafer yield model.

7. The method of claim 1, wherein the unit corresponds to a lot and the unit yield model is a lot yield model.

8. The method of claim 7, wherein the lot yield model is trained using the wafer yield model.

9. The method of claim 1, wherein the next testing step is the wafer sort testing.

10. The method of claim 1, wherein the current input data is a stream of real time input data.

11. The method of claim 1, wherein the recommending step further comprises a step of automatically implementing the recommended decision in a manufacturing execution system.
